(19) United States
(12) Patent Application Publication
(10) Pub. No.: US 2026/0250121 A1
(43) Pub. Date: Aug. 27, 2026

(54) MICROMECHANICAL COMPONENT FOR A SENSOR DEVICE, MICROPHONE DEVICE AND/OR MICRO-LOUDSPEAKER DEVICE

(71) Applicant: Robert Bosch GmbH, Stuttgart (DE)

(72) Inventors: Arne Dannenberg, Metzingen (DE); Isolde Simon, Kusterdingen (DE); Sophielouise Mach, Reutlingen (DE); Thomas Friedrich, Moessingen-Oeschingen (DE); Umidjon Nurmetov, Tuebingen (DE)

(21) Appl. No.: 18/854,586

(22) PCT Filed: May 15, 2023
(86) PCT No.: PCT/EP2023/062955

§ 371 Date: Oct. 7, 2024

(30) Foreign Application Priority Data
May 20, 2022 (DE) 10 2022 205 075.4

(51) Int. Cl. B81B 3/00; B81C 1/00; H04R 7/04; H04R 19/00; H04R 19/02; H04R 19/04; H04R 31/00

(52) U.S. Cl. CPC B81B 3/007; B81C 1/00658; H04R 7/04; H04R 19/005; H04R 19/02; H04R 19/04; H04R 31/003; B81B 2201/0257; B81B 2203/0127; B81C 2201/0109; H04R 2201/003

(57) ABSTRACT

A micromechanical component for a sensor device, microphone device and/or micro-loudspeaker device. The micromechanical component has a capping structure with an inner side of the capping structure which is oriented towards a sensitive surface of the micromechanical component and at least partially spans the sensitive surface of the micromechanical component, and with at least one air and/or medium access opening which is structured through the capping structure and extends in each case from the inner side of the capping structure to an outer side of the capping structure directed away from the inner side of the capping structure. The capping structure has at least two rib-like reinforcing structures projecting on the inner side of the capping structure, which reinforcing structures are oriented parallel to one another with a distance not equal to zero between two adjacent reinforcing structures.

### FIELD

The present invention relates to a micromechanical component for a sensor device, microphone device and/or micro-loudspeaker device. The present invention also relates to a manufacturing method for a micromechanical component for a sensor device, microphone device and/or micro-loudspeaker device.

### BACKGROUND INFORMATION

German Patent Application No. DE 10 2020 201 576 A1 describes a micromechanical component for a sensor device which has at least one stator electrode, at least one actuator electrode and a membrane spanning the electrodes with an outer side of the membrane facing away from the electrodes. In addition, a reinforcing and/or protective structure projecting on the outer side of the membrane is formed on the micromechanical component, which, for example, as a protective grid is to ensure particle protection for the outer side of the membrane to prevent contamination of the membrane.

### SUMMARY

The present invention provides a micromechanical component for a sensor device, microphone device and/or micro-loudspeaker device and a manufacturing method for a micromechanical component for a sensor device, microphone device and/or micro-loudspeaker device.

An example embodiment of the present invention provides micromechanical components which, due to their respective capping structure having the rib-like reinforcing structures, ensure more reliable protection of the sensitive surface of the respective micromechanical component against environmental influences, against contamination and against damage. In particular, the rib-like reinforcing structures of a micromechanical component according to the present invention ensure a high robustness of its capping structure even if the capping structure strikes an object. In a micromechanical component according to the present invention, even a relatively sensitive surface, such as a membrane surface of a warpable membrane used as a sensitive surface, is therefore hardly exposed to any risk of damage. Micromechanical components according to the present invention can therefore also be used reliably in aggressive surrounding areas with high impact loads. The present invention described here also provides micromechanical components with an increased service life compared to the related art. As will be explained in more detail below, the rib-like reinforcing structures on the inner side of the capping structure of a micromechanical component according to the present invention can also be formed by means of the present invention without a (significant) additional amount of work. Use of the present invention therefore does not increase/hardly increases the manufacturing costs for the respective micromechanical component.

If a silicone-containing gel is conventionally used as a protective layer for a membrane surface of a warpable membrane that fulfills the function of the sensitive surface, a total mass that can be set in warping movements is increased. The membrane surface, which is conventionally “protected” by the silicone-containing gel, therefore reacts more strongly to an acceleration of the device formed with the warpable membrane. In contrast, in a micromechanical component according to the present invention, the formation of the rib-like reinforcing structures on its capping structure does not lead to an increase in the total mass that can be set into warping movements. Acceleration of a micromechanical component according to the present invention with a membrane surface of a warpable membrane used as a sensitive surface therefore does not contribute/hardly contributes to the warping of the membrane. The increased protection of the membrane surface of the membrane used as a sensitive surface when using the present invention therefore does not affect the detection behavior of the membrane.

Likewise, the formation of a micromechanical component with a capping structure that is more robust due to its rib-like reinforcing structures contributes to better protection of the partially manufactured micromechanical component during its production. Accordingly, damage to the micromechanical component according to the present invention during transportation is reliably prevented due to its capping structure with the rib-like reinforcing structures projecting on the inner side.

In an advantageous embodiment of the micromechanical component of the present invention, the width of each of the at least two rib-like reinforcing structures can be defined perpendicular to their respective maximum length, wherein a distance between two adjacent reinforcing structures is at least a factor of 5 greater than the arithmetic mean of the widths of the at least two rib-like reinforcing structures. The spacing of the reinforcing structures from each other as described here contributes advantageously to increasing the robustness of the capping structure formed in each case.

According to an example embodiment of the present invention, alternatively or additionally, for each of the at least two rib-like reinforcing structures, their width aligned perpendicular to their respective maximum length can also be definable and a height by which the reinforcing structures protrude on the inner side of the capping structure can be greater by at least a factor of 2 than the arithmetic mean of the widths of the at least two rib-like reinforcing structures. This also contributes to increasing the robustness of the respective capping structure, so that even if an object strikes the capping structure, damage to the capping structure or the sensitive surface of the micromechanical component protected by it is not/is hardly of concern.

Advantageously, the sensitive surface of the micromechanical component can be a membrane surface of a warpable membrane. The present invention described here thus also makes an advantageous contribution to the protection of an otherwise comparatively sensitive surface from contamination and damage.

For example, the warpable membrane can be formed from a first semiconductor layer and the capping structure with the at least two rib-like reinforcing structures can be formed from a second semiconductor layer. As will become clear from the following description, the embodiment of the micromechanical component described here is comparatively simple and inexpensive to manufacture.

Performing a corresponding manufacturing method for a sensor device, microphone device and/or micro-loudspeaker device also provides the advantages explained above. It is expressly pointed out that the manufacturing method can be further developed in accordance with the embodiments of the micromechanical component explained above.

In an advantageous example embodiment of the manufacturing method of the present invention, the following substeps are carried out to arrange the capping structure adjacent to the sensitive surface of the micromechanical component and to simultaneously form the at least two rib-like reinforcing structures: Covering the sensitive surface of the micromechanical component at least partially with at least one sacrificial layer, structuring at least two trenches aligned parallel to one another in the at least one sacrificial layer with a distance not equal to zero between two adjacent trenches, and depositing a semiconductor layer on the at least one sacrificial layer, the at least two rib-like reinforcing structures being formed by filling the trenches with the material of the semiconductor layer. The sub-steps described here can be carried out cost-effectively using standard semiconductor processes.

According to an example embodiment of the present invention, preferably, a first sacrificial layer is first formed as the at least one sacrificial layer on the sensitive surface of the micromechanical component in such a way that the first sacrificial layer at least partially covers the sensitive surface of the micromechanical component, wherein at least three auxiliary trenches aligned parallel to one another with a distance not equal to zero between two adjacent auxiliary trenches are structured in the first sacrificial layer, after structuring the auxiliary trenches, a second sacrificial layer is deposited as the at least one sacrificial layer on the first sacrificial layer in such a way that the auxiliary trenches are covered as cavities by the second sacrificial layer, and wherein the at least two trenches aligned parallel to one another are patterned into the second sacrificial layer. As will become clear from the following description, the formation of the cavities facilitates subsequent removal of the sacrificial layer material of the first sacrificial layer and of the second sacrificial layer by means of an etching process.

In particular, the at least two trenches aligned parallel to each other can be structured in the second sacrificial layer in such a way that a projection of each trench along an axis aligned perpendicular to the sensitive surface lies in the first sacrificial layer between two adjacent cavities. In this case, the cavities are positioned in such a way that they accelerate the etching process for removing the sacrificial layer material of the first sacrificial layer and of the second sacrificial layer and at the same time enable reliable removal of the sacrificial layer material even in intermediate regions between two adjacent reinforcing structures.

In a further advantageous embodiment of the manufacturing method of the present invention, the capping structure is anchored to a further semiconductor layer, from which a warpable membrane is formed with the sensitive surface of the micromechanical component as the membrane surface, by exposing a partial surface of the further semiconductor layer from the first sacrificial layer and the second sacrificial layer before the semiconductor layer is deposited. By means of the anchoring of the capping structure to the further semiconductor layer realized in this way, a warpable region of the warpable membrane can be advantageously defined/limited by preventing surrounding regions of the further semiconductor layer lying around the membrane from also being warped when the membrane is warped.

### BRIEF DESCRIPTION OF THE DRAWINGS

Further features and advantages of the present invention are explained below with reference to the figures.

FIG. 1 shows a schematic illustration of a first example embodiment of the micromechanical component according to the present invention.

FIG. 2 shows a schematic representation of a second example embodiment of the micromechanical component according to the present invention.

FIGS. 3A to 3E schematic representations of cross-sections through intermediate products to explain an example embodiment of the manufacturing method for a micromechanical component according to the present invention.

### DETAILED DESCRIPTION OF EXAMPLE EMBODIMENTS

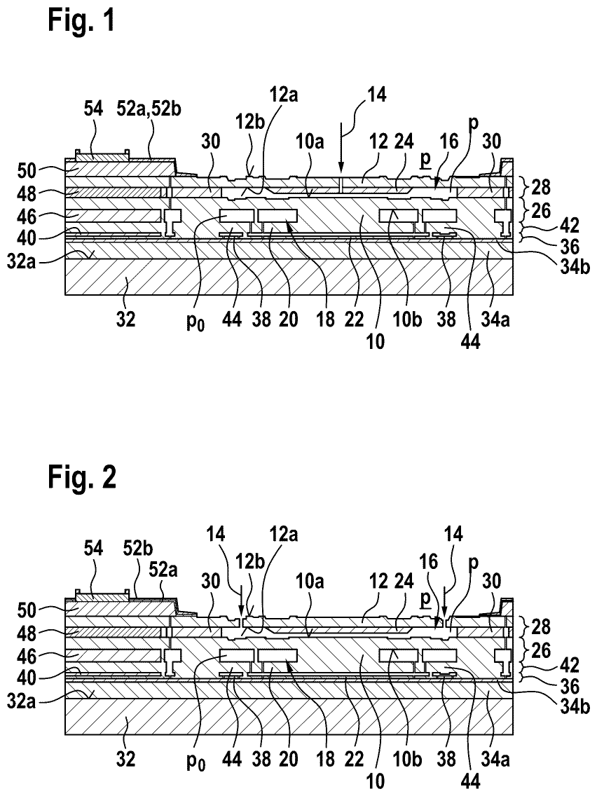

FIG. 1 is a schematic illustration of a first embodiment of the micromechanical component.

The micromechanical component shown schematically in FIG. 1 can be used as (at least part of) a sensor device, microphone device and/or micro-loudspeaker device. By way of example only, the micromechanical component of FIG. 1 can be used as a pressure sensor, wherein a membrane surface 10a of a warpable membrane 10 of the micromechanical component is used as a sensitive surface 10a in order to measure a pressure difference between a pressure p present in an external surrounding area of the micromechanical component and a predetermined reference pressure po. However, it is pointed out here that the development of the micromechanical component described below, in particular of its capping structure 12, is not limited to a specific type of sensor.

The capping structure 12 serves to protect the sensitive surface 10a of the micromechanical component and has an inner side 12a aligned with the sensitive surface 10a of the micromechanical component, which at least partially spans the sensitive surface 10a. In contrast, an outer side 12b of the capping structure 12 is directed away from the inner side 12a and away from the sensitive surface 10a of the micromechanical component. In addition, the capping structure 12 is formed with at least one air and/or medium access opening 14 structured by the capping structure, wherein the at least one air and/or medium access opening 14 extends in each case from the inner side 12a of the capping structure 12 to the outer side 12b of the capping structure 12. By way of example only, the micromechanical component of FIG. 1 has only a single air and/or medium access opening 14, which extends centrally through the capping structure 12. However, it should be noted that the design of the capping structure 12 outlined in FIG. 1 with only one air and/or medium access opening 14 is only to be interpreted as an example.

The at least one air and/or medium access opening 14 ensures, for example, that the pressure p present in the external surrounding area of the micromechanical component is also present in a measuring volume 16 of the micromechanical component formed between the sensitive surface 10a of the micromechanical component and the inner side 12a of the capping structure 12. The reference pressure po is enclosed in a reference volume 18, which is bounded by an inner side 10b of the membrane 10 facing away from the sensitive surface 10a. In addition, at least one actuator or sensing electrode 20 is suspended from the inner side 10b of the membrane 10, which is/can be adjusted in relation to at least one fixedly arranged stator electrode 22 by means of a warping of the membrane 10 triggered by the pressure difference between the pressure p and the reference pressure po. The pressure difference between the pressure p and the reference pressure po can therefore be determined on the basis of an evaluation of a voltage or capacitance applied between the at least one actuator or sensing electrode 20 and the at least one stator electrode 22.

As can be seen in FIG. 1, the capping structure 12 has at least two rib-like reinforcing structures 24 projecting on the inner side 12a of the capping structure 12. The at least two rib-like reinforcing structures 24 of the capping structure 12 are aligned parallel to each other, with a distance not equal to zero between two adjacent reinforcing structures 24. Each of the reinforcing structures 24 thus has its maximum length in a common spatial direction, which in the micromechanical component of FIG. 1 lies in the image plane. Possibly, the at least one air and/or medium access opening 14 can also extend through at least one of the reinforcing structures 24.

The design of the capping structure 12 described here, with its at least two rib-like reinforcing structures 24 projecting on the inner side 12a, advantageously increases the robustness of the capping structure 12. The capping structure 12 formed with the reinforcing structures 24 can therefore better fulfill its task as a protective structure or protective layer for protecting the sensitive surface 10a of the micromechanical component from environmental influences, from contamination and from damage. Even a conventionally relatively sensitive surface 10a, such as the membrane surface 10a of the warpable membrane 10 shown in FIG. 1, can therefore perform its function more reliably. Even an impact of an object on the outer side 12b of the capping structure 12 does not usually lead to incorrect measurements when determining the pressure difference between the pressure p and the reference pressure po or to damage to the sensitive surface 10a. Furthermore, the capping structure 12 also protects the sensitive surface 10a from the presence of foreign particles in the measuring volume 16 and from wetting of the sensitive surface 10a with a liquid. Furthermore, it can also be seen from FIG. 1 that the advantageous design of the capping structure 12 with the at least two rib-like reinforcing structures 24 on its inner side 12a does not impair/hardly impairs a detection behavior of the membrane 10.

For each of the at least two rib-like reinforcing structures 24, their width aligned perpendicular to their maximum length (perpendicular to the image plane of FIG. 1) can also be defined. Preferably, a distance between two adjacent reinforcing structures 24 is greater by at least a factor of 5, in particular by at least a factor of 10, than the arithmetic mean of the widths of the at least two rib-like reinforcing structures 24. Alternatively or additionally, a height by which the reinforcing structures 24 protrude on the inner side 12a of the capping structure 12 may be greater than the arithmetic mean of the widths of the at least two rib-like reinforcing structures 24 by at least a factor of 2, in particular by at least a factor of 5. The spacing and shapes of the reinforcing structures 24 described here ensure an advantageous robustness of the capping structure 12 formed in each case.

While the warpable membrane 10 can be formed from a first semiconductor layer 26, for example a polysilicon layer 26, the capping structure 12 with the at least two rib-like reinforcing structures 24 can be formed from a second semiconductor layer 28, in particular a polysilicon layer 28. At least one anchoring region 30 (formed from the second semiconductor layer 28) may also protrude on the inner side 12a of the capping structure 12, which mechanically contacts the first semiconductor layer 26 such that the capping structure 12 is anchored to the first semiconductor layer 26 via its at least one anchoring region 30. By means of the formation of the at least one anchoring region 30 of the capping structure 12, surrounding regions of the first semiconductor layer 26 surrounding the membrane 10 can be “fixed” in such a way that, when the membrane 10 is warped, undesired co-warping movements of the surrounding regions are prevented due to their fixation by means of the at least one anchoring region 30. A warping behavior of the membrane 10 can thus be optimized by means of a corresponding positioning of the at least one anchoring region 30.

By way of example, the micromechanical component of FIG. 1 has a substrate 32, in which a substrate surface 32a is at least partially covered with at least one insulating layer 34a and 34b. In particular, the substrate 32 can be a silicon substrate 32. The at least one insulating layer 34a and 34b can be, for example, a silicon dioxide layer 34a and/or a silicon rich silicon nitride layer 34b. A first electrode layer 36, such as a polysilicon layer 36, is deposited on the at least one insulating layer 34a and 34b, from which at least the at least one stator electrode 22 is structured. Optionally, at least one reference counter electrode 38 and/or at least one conductor track can also be structured out of the first electrode layer 36. A second electrode layer 42, from which the at least one actuator or sensing electrode 20 and possibly also at least one reference electrode 44 are structured, can be deposited on a first sacrificial layer 40, in particular a silicon dioxide layer 40, which at least partially covers the structured first electrode layer 36. The second electrode layer 42 can also be a polysilicon layer 42. The first semiconductor layer 26 may be deposited over a second sacrificial layer 46, for example a silicon dioxide layer 46, which at least partially covers the second electrode layer 42. At least one further sacrificial layer 48, in particular at least one further silicon dioxide layer 48, may be formed between the first semiconductor layer 26 and the second semiconductor layer 28. After at least partial removal of the sacrificial layers 40, 46 and 48 to expose the measuring volume 16 and the reference volume 18, the membrane 10 can be warped in response to the pressure difference between the pressure p and the reference pressure po so that the desired pressure measurements can be carried out by means of the micromechanical component.

As can be seen in FIG. 1, the second semiconductor layer 28 can also be used for depositing further layers, such as at least one conductive layer 50 and/or at least one insulating layer 52a and 52b and/or for fixing at least one contact structure 54.

FIG. 2 is a schematic illustration of a second embodiment of the micromechanical component.

The micromechanical component shown schematically in FIG. 2 differs from the above-described embodiment only in the positioning of its at least one air and/or medium access opening 14. As can be seen in FIG. 2, several air and/or medium access openings 14 can also be structured by the capping structure 12. As an example, the air and/or medium access openings 14 in the micromechanical component of FIG. 2 are located at an edge region of the capping structure 12, which is kept free of the rib-like reinforcing structures 24, but is surrounded by the at least one anchoring region 30. With regard to further features and properties of the micromechanical component of FIG. 2 and its advantages, reference is made to the embodiment described above.

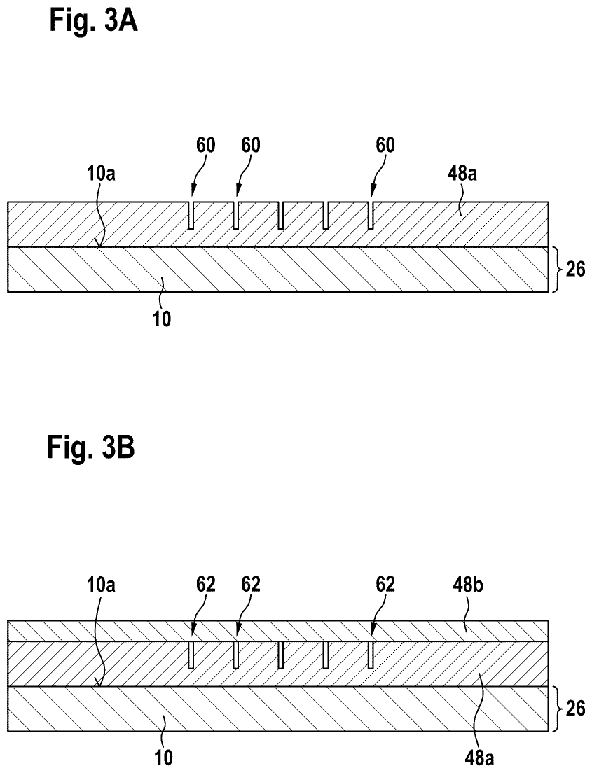

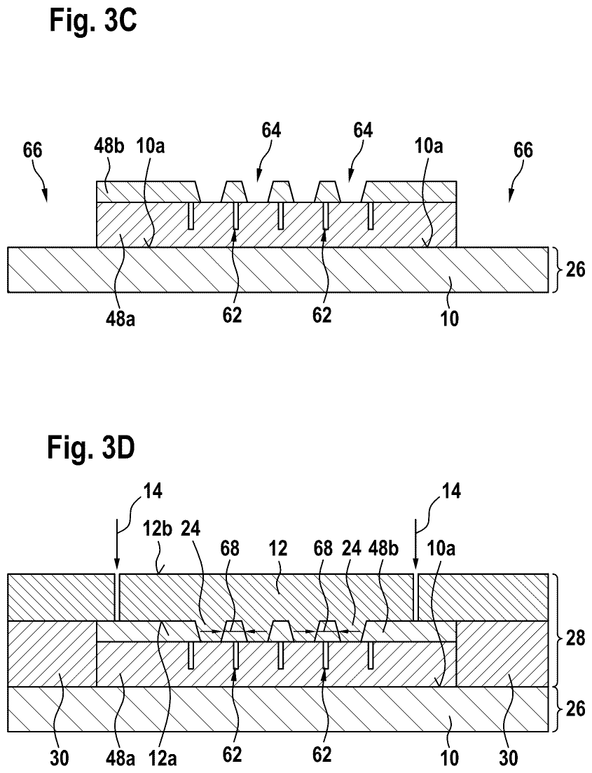

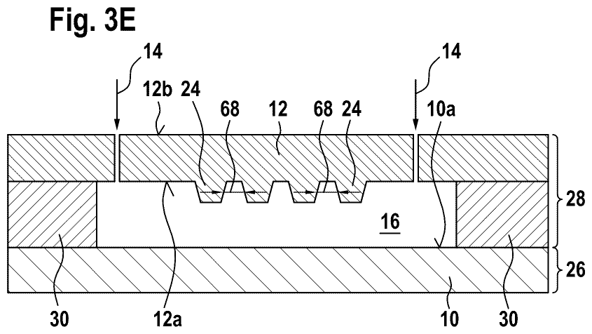

FIGS. 3A to 3E show schematic representations of cross-sections through intermediate products to explain an embodiment of the manufacturing method for a micromechanical component.

The manufacturing method described below can be used to produce a variety of different sensor devices, microphone devices and/or micro-loudspeaker devices. For example, the method steps described below can be carried out to produce the micromechanical components described above. However, it should be noted that the feasibility of the manufacturing method is not limited to the production of one of the micromechanical components described above.

By means of the method steps described below, a capping structure 12 is arranged adjacent to a sensitive surface 10a of the subsequent micromechanical component in such a way that an inner side 12a of the capping structure 12, which is aligned with the sensitive surface 10a of the micromechanical component, at least partially spans the sensitive surface 10a. By way of example only, the capping structure 12 formed by means of the manufacturing method described here is arranged on a first semiconductor layer 26, from which a warpable membrane 10 is formed with the sensitive surface 10a of the micromechanical component as membrane surface 10a. The first semiconductor layer 26 can, for example, be a polysilicon layer 26. However, the feasibility of the method steps described below is not limited to a sensitive surface 10 formed as a membrane surface 10a of a warpable membrane 10.

To arrange the capping structure 12 adjacent to the sensitive surface 10a, the sensitive surface 10a of the micromechanical component is at least partially covered with at least one sacrificial layer 48a and 48b. Specifically, as the at least one sacrificial layer 48a and 48b in the embodiment of the manufacturing method described herein, a first sacrificial layer 48a, preferably a silicon dioxide layer 48a, is first formed on the sensitive surface 10a such that the first sacrificial layer 48a at least partially covers the sensitive surface 10a.

FIG. 3A shows the intermediate product after structuring at least three auxiliary trenches 60 aligned parallel to each other into the first sacrificial layer 48a with a distance not equal to zero between two adjacent auxiliary trenches 60. Preferably, the structuring of the auxiliary trenches 60 into the first sacrificial layer 48a is carried out by means of an anisotropic etching step using an etching mask (not shown).

As can be seen in FIG. 3B, after structuring the auxiliary trenches 60, a second sacrificial layer 48b, for example a silicon dioxide layer 48b, is deposited as the at least one sacrificial layer 48a and 48b on the first sacrificial layer 48a such that the auxiliary trenches 60 are covered as cavities 62 by the second sacrificial layer 48b. The auxiliary trenches 60 are preferably structured into the first sacrificial layer 48a with an extension aligned perpendicular to the sensitive surface 10a, which is so small that the auxiliary trenches 60 are not/are barely filled up when the second sacrificial layer 48b is deposited. The advantages of cavities 62 are discussed in more detail below.

In order to form the above-described reinforcing structures 24 on the capping structure 12 formed by means of the method steps described herein, at least two trenches 64 aligned parallel to each other with a distance not equal to zero between two adjacent trenches 64, are structured into the at least one sacrificial layer 48a and 48b. In the embodiment of the manufacturing method described here, the trenches are structured specifically in the second sacrificial layer 48b. By means of a respective position and shape of the trenches 64, a respective position and extent of the subsequent reinforcing structures 24 can be determined.

Preferably, the trenches 64 are structured by carrying out an anisotropic etching step using an etching mask (not shown). In the embodiment described herein, the at least two trenches 64 aligned parallel to each other are further structured into the second sacrificial layer 48b such that a projection of each trench 64 along an axis aligned perpendicular to the sensitive surface 10a lies in the first sacrificial layer 48a between two adjacent cavities 62. The advantages of such positioning of the cavities 62 in the first sacrificial layer 48a relative to the trenches 64 in the second sacrificial layer 48b will be discussed below.

In order to anchor the subsequently formed capping structure 12 to the first semiconductor layer 26, at least a partial surface of the first semiconductor layer 26 is exposed from the first sacrificial layer 48a and the second sacrificial layer 48b after depositing of the second semiconductor layer 28 and preferably also after structuring of the trenches 64. For this purpose, for example, at least one continuous recess 66 is etched through the first sacrificial layer 48a and the second sacrificial layer 48b using an etching mask. The intermediate product formed in this way is shown in FIG. 3C.

In the manufacturing method described here, the capping structure 12 is formed adjacent to the sensitive surface 10a simultaneously with the formation of its at least two rib-like reinforcing structures 24 by depositing a second semiconductor layer 28, such as in particular a polysilicon layer 28. It can be seen that when the second semiconductor layer 28 is deposited on the at least one sacrificial layer 48a and 48b, the at least two rib-like reinforcing structures 24 projecting on the inner side 12a of the capping structure 12 are formed by filling the former trenches 64 (with the material of the second semiconductor layer 28). Due to the parallel alignment of the earlier trenches 64, the rib-like reinforcing structures 24 are also aligned parallel to each other.

By filling the at least one continuous recess 66 (with the material of the second semiconductor layer 28), at least one anchoring region 30 is also formed, which protrudes on the inner side 12a of the capping structure 12 and via which the capping structure 12 is anchored to the first semiconductor layer 26. It can be seen that the arrangement of the cavities 62 and the trenches 64 relative to each other as described above positions the cavities 62 in the first sacrificial layer 48a relatively close to intermediate regions 68 between two adjacent reinforcing structures 24. The advantages of this position of the cavities 62 in relation to the intermediate regions 68 are explained below.

FIG. 3D shows the intermediate product after the structuring of at least one air and/or medium access opening 14 through the capping structure 12 in such a way that the at least one structured air and/or medium access opening 14 extends in each case from the inner side 12a of the capping structure 12 to an outer side 12b of the capping structure 12 aligned away from the inner side 12a. To structure the at least one air and/or medium access opening 14, a further anisotropic etching step can be carried out using an etching mask (not shown). The structuring of the at least one air and/or medium access opening 14 of the capping structure 12 can take place relatively late in the manufacturing process of the micromechanical component, when all process steps in which particles are released and/or a liquid is sprayed have already been completed. Thus, it is not to be feared that particles and/or a liquid penetrate into the at least one air and/or medium access opening 14 and possibly later via the at least one air and/or medium access opening 14 into the subsequently formed measuring volume 16.

After structuring the at least one air and/or medium access opening 14, a gas phase etching process may be performed to remove at least a portion of the sacrificial layer material of the at least one sacrificial layer 48a and 48b from the measurement volume 16 (and possibly also from the reference volume 18 not shown). As can be seen in FIG. 3E, the cavities 62 facilitate and accelerate the at least partial removal of the sacrificial layer material of the at least one sacrificial layer 48a and 48b from the measurement volume 16. In particular, provided that the trenches 64 are structured with respect to the cavities 62 in the second sacrificial layer 48b such that a projection of each trench 64 along the axis aligned perpendicular to the sensitive surface 10a lies in the first sacrificial layer 48a between two adjacent cavities 62, the cavities 62 are/will be advantageously positioned to the conventionally etch-critical intermediate regions 68 between two adjacent reinforcing structures 24 (see FIG. 3D). This facilitates the removal of the sacrificial layer material of the at least one sacrificial layer 48a and 48b also from the intermediate regions 68. This reliably prevents unwanted residues of the sacrificial layer material in the measuring volume 16.

In a method step not shown in FIG. 3E, optionally at least one hydrophobic material, such as fluoropolymer, can be deposited on the at least one air and/or medium access opening 14, wherein undesired penetration of liquids into the measuring volume 16 via the at least one air and/or medium access opening 14 coated with the hydrophobic material can be additionally prevented. If the reference cavern 18 (not shown) is also exposed in the gas phase etching process, a desired pressure value for the reference pressure po in the reference cavern 18 can then be set before the reference cavern 18 is sealed air-tight and gas-tight.

Although the present invention is explained above with reference to pressure sensors, its applicability is not limited to this type of sensor. For example, the present invention can also be used for a chemical detection sensor whose sensitive surface 10a reacts to the absorption of a detection substance on the sensitive surface 10a with a detectable change in its electrical properties.

The present invention can be applied to smartphones, tablets, wearables, hearables, drones, robots, games, toys, calorie counting devices, motion control devices, free fall detection devices, motion detection devices, ear detection devices, head movement detection devices, air quality detection devices, climate control devices, ground level detection devices, water level detection devices, senior care devices, indoor navigation, position tracking, flight control and/or altitude stabilization.

1-10. (canceled)

11. A micromechanical component for a sensor device and/or a microphone device and/or a micro-loudspeaker device, comprising:
a capping structure, an inner side of the capping structure being oriented towards a sensitive surface of the micromechanical component and at least partially spanning the sensitive surface of the micromechanical component, and having at least one air and/or medium access opening which is structured through the capping structure and extends in each case from the inner side of the capping structure to an outer side of the capping structure directed away from the inner side of the capping structure; and
at least two rib-like reinforcing structures projecting on the inner side of the capping structure, the reinforcing structures being oriented parallel to one another with a distance not equal to zero between two adjacent ones of the reinforcing structures.

12. The micromechanical component according to claim 11, wherein for each of the at least two rib-like reinforcing structures, its width oriented perpendicular to its respective maximum length can be defined and a distance between two adjacent ones of the reinforcing structures is greater by at least a factor of 5 than a arithmetic mean of the widths of the at least two rib-like reinforcing structures.

13. The micromechanical component according to claim 11, wherein for each of the at least two rib-like reinforcing structures, it width aligned perpendicular to its respective maximum length can be defined and a height by which the reinforcing structures protrude on the inner side of the capping structure is greater by at least a factor of 2 than an arithmetic mean of the widths of the at least two rib-like reinforcing structures.

14. The micromechanical component according to claim 11, wherein the sensitive surface of the micromechanical component is a membrane surface of a warpable membrane.

15. The micromechanical component according to claim 14, wherein the warpable membrane is formed from a first semiconductor layer and the capping structure with the at least two rib-like reinforcing structures is formed from a second semiconductor layer.

16. A manufacturing method for a micromechanical component for a sensor device and/or a microphone device and/or a micro-loudspeaker device, comprising the following steps:
arranging a capping structure adjacent to a sensitive surface of the micromechanical component in such a way that an inner side of the capping structure, which is aligned with the sensitive surface of the micromechanical component, at least partially spans the sensitive surface of the micromechanical component;
structuring at least one air and/or medium access opening through the capping structure in such a way that the at least one structured air and/or medium access opening extends in each case from the inner side of the capping structure to an outer side of the capping structure directed away from the inner side of the capping structure; and
forming at least two rib-like reinforcing structures, which protrude on the inner side of the capping structure and are aligned parallel to each other with a distance not equal to zero between two adjacent ones of the reinforcing structures.

17. The manufacturing method according to claim 16, wherein the following substeps are carried out for arranging the capping structure adjacent to the sensitive surface of the micromechanical component and for simultaneously forming the at least two rib-like reinforcing structures:
covering the sensitive surface of the micromechanical component at least partially with at least one sacrificial layer;
structuring at least two trenches aligned parallel to each other into the at least one sacrificial layer with a distance not equal to zero between two adjacent ones of the trenches; and
depositing a semiconductor layer on the at least one sacrificial layer, wherein the at least two rib-like reinforcing structures are formed by filling the trenches with a material of the semiconductor layer.

18. The manufacturing method according to claim 17, wherein, as the at least one sacrificial layer, a first sacrificial layer is first formed on the sensitive surface of the micromechanical component in such a way that the first sacrificial layer at least partially covers the sensitive surface of the micromechanical component, wherein at least three auxiliary trenches aligned parallel to one another with a distance not equal to zero between two adjacent ones of the auxiliary trenches are structured into the first sacrificial layer, wherein, after structuring the auxiliary trenches, a second sacrificial layer is deposited as the at least one sacrificial layer on the first sacrificial layer in such a way that the auxiliary trenches are covered as cavities by the second sacrificial layer, and wherein the at least two trenches aligned parallel to one another are structured into the second sacrificial layer.

19. The manufacturing method according to claim 18, wherein the at least two trenches aligned parallel to each other are structured into the second sacrificial layer such that a projection of each trench along an axis aligned perpendicular to the sensitive surface lies in the first sacrificial layer between two adjacent cavities.

20. The manufacturing method according to claim 18, wherein the capping structure is anchored to a further semiconductor layer, from which a warpable membrane with the sensitive surface of the micromechanical component as a membrane surface is formed, by exposing a partial surface of the further semiconductor layer from the first sacrificial layer and the second sacrificial layer before the semiconductor layer is deposited.
